(19) United States
(12) Patent Application Publication
(10) Pub. No.: US 2009/0091020 A1
(43) Pub. Date: Apr. 9, 2009

(54) CO-FIRED CERAMIC MODULE

(75) Inventors: Chih-Hung WEI, Taoyuan Hsien (TW); Yu-Ping HSIEH, Taoyuan Hsien (TW)

Correspondence Address: Muncy, Geissler, Olds & Lowe, PLLC, P.O. BOX 1364, FAIRFAX, VA, 22038-1364, US

(73) Assignee: DELTA ELECTRONICS, INC.

(21) Appl. No.: 12/106,769

(22) Filed: Apr. 21, 2008

(30) Foreign Application Priority Data
Oct. 5, 2007 (TW) 096137365

(51) Int. Cl. H01L 23/373

(52) U.S. Cl. 257/705; 257/E23.113

(57) ABSTRACT

A co-fired ceramic module includes a ceramic substrate and at least one heat-emitting device. The ceramic substrate has at least one high thermal conductivity material. The heat-emitting device is disposed on the ceramic substrate. The substrate further includes a cavity and the heat-emitting device is disposed in the cavity.

### CROSS REFERENCE TO RELATED APPLICATIONS

This Non-provisional application claims priority under 35 U.S. §119(a) on Patent Application No(s). 096137365 filed in Taiwan, Republic of China on Oct. 5, 2007, the entire contents of which are hereby incorporated by reference.

### BACKGROUND OF THE INVENTION

1. Field of Invention

The invention relates to a ceramic module and, in particular, to a co-fired ceramic module.

2. Related Art

Recently, portable information electronic products and mobile communication products are developed toward the miniaturized, multi-functional, highly reliable and low priced trends, so the high-element density has become the developing trend of the electronic product. Therefore, active devices and passive devices used in the circuit have been developed toward the integrated, modularized and on-chip directions so that the size of the circuit can be effectively reduced, the cost can be lowered and the competition ability of the product can be enhanced.

However, the reduction of the size brings the heat dissipating problem. Because the conventionally circuit board made of resin pertains to a material having the poor heat conducting property, the structure of the circuit board has to be changed to enhance the heat dissipating efficiency. For example, a plurality of thermal via holes may be formed on the circuit board so that the heat of the electronic element disposed on the circuit board is dissipated from the thermal via holes. However, the circuit board has to be punched and the original structure thereof is damaged. Consequently, the production time is lengthened, the original structural intensity of the circuit board is also decreased and the reliability of the electronic element is thus deteriorated.

Based on the above-mentioned problems, some manufacturers have recently paid attention to the research of the low-temperature co-fired ceramics (LTCC) technology actively. The size availability of the electronic product is enhanced according to the property that the thermoconductive efficiency thereof is better than that of the conventional circuit board.

Therefore, it is an important subject to provide a co-fired ceramic module for providing a high thermoconductive efficiency without additional punching, thereby reducing the production time, preventing the original structural intensity from being damaged, and enhancing the reliability.

### SUMMARY OF THE INVENTION

In view of the foregoing, the invention is to provide a co-fired ceramic module for providing a high thermoconductive efficiency without additional machining.

To achieve the above, the invention discloses a co-fired ceramic module including a ceramic substrate and at least one heat-emitting device. The ceramic substrate has at least one high thermal conductivity material. The heat-emitting device is disposed on the ceramic substrate.

As mentioned above, the high thermal conductivity material is added to the co-fired ceramic module of the invention and then co-fired with the co-fired ceramic module to form the ceramic substrate. Thus, the high thermoconductive efficiency can be provided to the heat-emitting device. Compared with the prior art, the invention can have the high thermoconductive efficiency without modifying the structure of the sintered ceramic substrate so that the production time can be saved, the original structural intensity is free from being damaged, and the reliability is enhanced.

Further scope of the applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings winch are given by way of illustration only, and thus are not limitative of the present invention, and wherein:

FIG. 1 is a cross-sectional illustration showing a co-fired ceramic module according to a first embodiment of the present invention;

FIG. 2 is a cross-sectional illustration showing a co-fired ceramic module according to a second embodiment of the present invention;

FIG. 3 is a cross-sectional illustration showing a co-fired ceramic module according to a third embodiment of the present invention;

FIG. 4 is a cross-sectional illustration showing a co-fired ceramic module according to a fourth embodiment of the present invention;

FIG. 5 is a schematic illustration showing a co-fired ceramic module having a cavity according to a fifth embodiment of the present invention;

FIGS. 6A to 6C are cross-sectional illustrations showing different shapes of inner edges of cavities of the co-fired ceramic module shown in FIG. 5;

FIG. 7 is a schematic illustration showing a co-fired ceramic module having a plurality of cavities according to the fifth embodiment of the present invention;

FIG. 8 is a cross-sectional illustration showing a co-fired ceramic module according to a sixth embodiment of the present invention; and

FIG. 9 is a cross-sectional illustration showing a co-fired ceramic module according to a seventh embodiment of the present invention.

### DETAILED DESCRIPTION OF THE INVENTION

The present invention will be apparent from the following detailed description, which proceeds with reference to the accompanying drawings, wherein the same references relate to the same elements.

### First Embodiment

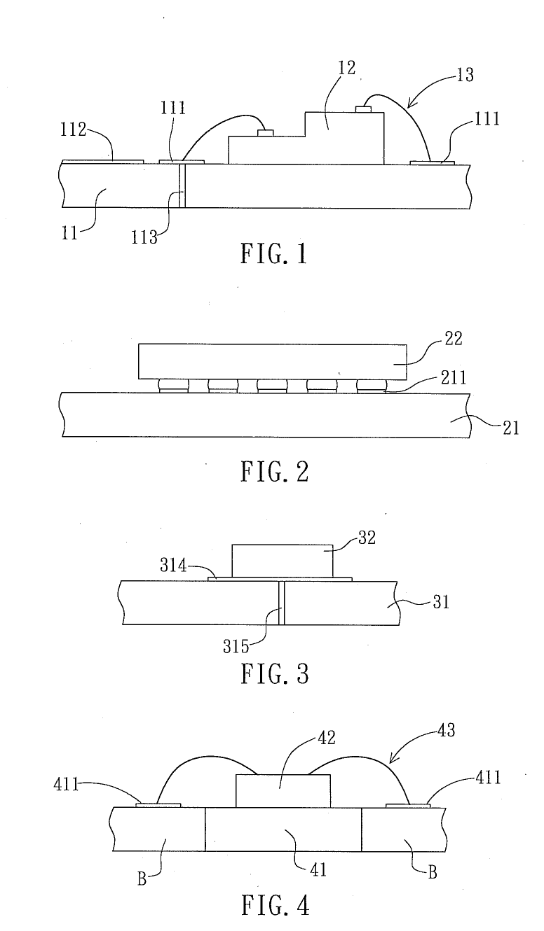

Referring to FIG. 1, a co-fired ceramic module 1 according to a first embodiment of the present invention includes a ceramic substrate 11 and at least one heat-emitting device 12. The ceramic substrate 11 has at least one high thermal conductivity material. The high thermal conductivity material has a high coefficient of heat conductivity, and is, for example but not limited to, aluminum nitride, silicon carbide, sapphire or beryllium oxide (BeO). The heat-emitting device 12 is disposed on the ceramic substrate 11. Herein, the heat-emitting device 12 is disposed on a surface of the ceramic substrate 11.

The ceramic substrate 11 is a low-temperature co-fired ceramics (LTCC) substrate and can be a multi-layer or single-layer plate. The method of preparing the ceramic substrate 11 will be described with reference to the single-layer plate. First, a ceramic material, an inorganic adhesive, the high thermal conductivity material and other necessary materials are mixed to form slurry. Then, the slurry is shaped to form a pre-mold plate by a scraper. Finally, the pre-mold plate is sintered at the temperature lower than 1000° C. so that the ceramic substrate 11 is obtained.

The type of the ceramic substrate 11 is not particularly restricted in this invention. For example, the ceramic substrate 11 can be a carrier or a circuit board. In addition, the type of the heat-emitting device 12 is not particularly restricted, and the heat-emitting device 12 can be an electronic element, such as a passive device or an active device, which generates and emits heat when it is operating. The passive device can be a resistor, a capacitor and an inductor. The active device can be a chip or a package body, for example, and the chip or the package body can be a light-emitting diode (LED) or a solar cell.

In this embodiment, the heat-emitting device 12 is a LED chip and the ceramic substrate 11 is a carrier. The ceramic substrate 11 has a plurality of connection pads 111 and a patterned circuit 112. The heat-emitting device 12 is connected to the connection pad 111 by a wire 13, and the connection pads 111 are electrically connected to the patterned circuit 112. Of course, the heat-emitting device 12 is connected to the ceramic substrate 11 in a manner, such as flip-chip bonding, determined according to the type or requirement. In addition, the connecting material may also be changed to an intermetallic material, solder tin or silver paste.

In addition, the ceramic substrate 11 has a via hole 113 for transmitting an electric signal. The number and the positions of the via holes 113 can be changed according to different requirements. For example, the number of layers of the ceramic substrate 11 and the circuit layout can be changed.

In this embodiment, the ceramic substrate 11 has the high thermal conductivity material. Thus, the thermoconductive path of the ceramic substrate 11 simultaneously includes a horizontal path and a vertical path, and the electroconductive path simultaneously includes a horizontal path and a vertical path. For example, the electroconductive path of the via hole 113 is the vertical path, and the electroconductive path of the patterned circuit 112 is the horizontal path. As mentioned hereinabove, the electroconductive path and the thermoconductive path of the ceramic substrate 11 may be in parallel to or perpendicular to each other. That is, the electroconductive path and the thermoconductive path can extend in the same direction or different directions.

### Second Embodiment

Referring to FIG. 2, a co-fired ceramic module 2 according to a second embodiment of the present invention includes a ceramic substrate 21 and at least one heat-emitting device 22. The second embodiment is different from the first embodiment mainly in that the ceramic substrate 21 is a circuit board, and the heat-emitting device 22 is a package body. Herein, the heat-emitting device 22 is directly disposed on connection pads 211 of the ceramic substrate 21 by way of the ball grid array (BGA) package. In addition, the heat-emitting device 22 can also be disposed on the ceramic substrate 21 in other manners, such as the quad flat package (QFP), the surface mount technology (SMT) or the pin grid array (PGA) package.

### Third Embodiment

Referring to FIG. 3, a co-fired ceramic module 3 according to a third embodiment of the present invention includes a ceramic substrate 31 and at least one heat-emitting device 32 disposed on the ceramic substrate 31. The ceramic substrate 31 has a metal layer 314 and a thermal via hole 315. The metal layer 314 is connected to the heat-emitting device 32. The metal layer 314 and the thermal via hole 315 can increase the thermoconductive efficiency of the ceramic substrate 31.

### Fourth Embodiment

Referring to FIG. 4, a co-fired ceramic module 4 according to a fourth embodiment of the present invention includes a ceramic substrate 41 and at least one heat-emitting device 42 disposed on the ceramic substrate 41. A circuit board B includes a plurality of connection pads 411 disposed on a surface of the circuit B and is formed on the same layer of the ceramic substrate 41. The heat-emitting device 42 is connected to the connection pad 411 by a wire 411. In this embodiment, the ceramic substrate 41 mainly provides the thermoconductive property, and the circuit board B is for transferring the electric signal.

### Fifth Embodiment

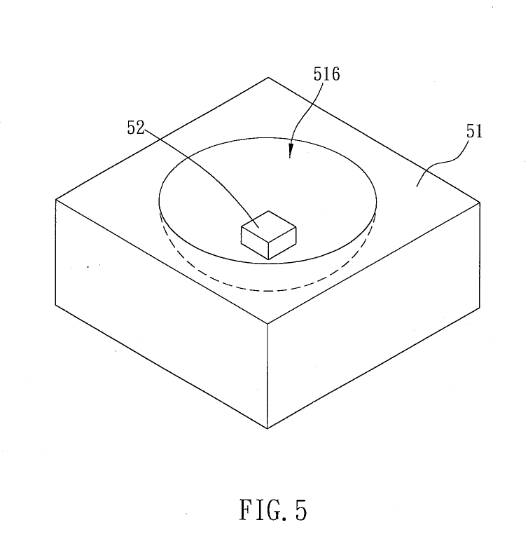

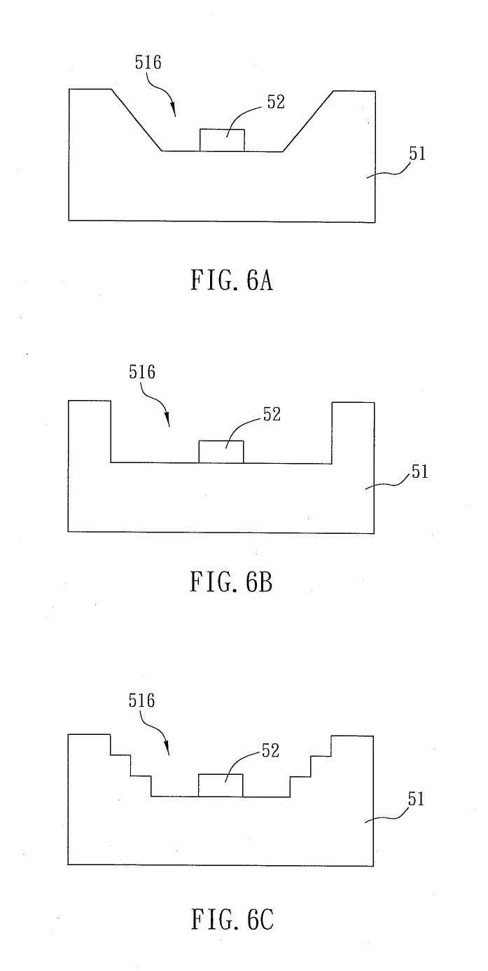

Referring to FIG. 5, a co-fired ceramic module 5 according to a fifth embodiment of the present invention includes a ceramic substrate 51 and at least one heat-emitting device 52. The ceramic substrate 51 has at least one cavity 516, and the heat-emitting device 52 is disposed in the cavity 516. As shown in FIG. 5, the shape of the inner edge of the cavity 516 is curved. Based on the concept of the present invention, the surface of the cavity 516 can be inclined, upright or ladder-like, as shown in FIGS. 6A, 6B and 6C, respectively. The shape of the inner edge of the cavity 516 is not particularly restricted and can be changed according to the requirement.

The cavity 516 may be formed according to various methods. For example, the pre-mold plate is first punched and then sintered. Alternatively, the cavity 516 is shaped by way of planning, scraping, grinding or imprinting, and then the cavity 516 is sintered and polished. Alternatively, the pre-mold plate is firstly sintered, and then the cavity 516 is shaped by way of planning, scraping or grinding. Alternatively, the pre-mold plate is first punched to constitute a model of the cavity 516 and then shaped by way of planning, scraping, grinding or imprinting, and then sintered and polished. Alternatively, the pre-mold plate is first punched to constitute a model of the cavity 516 and then sintered. Then, the cavity 516 is formed by way of sintering, planning, scraping or grinding.

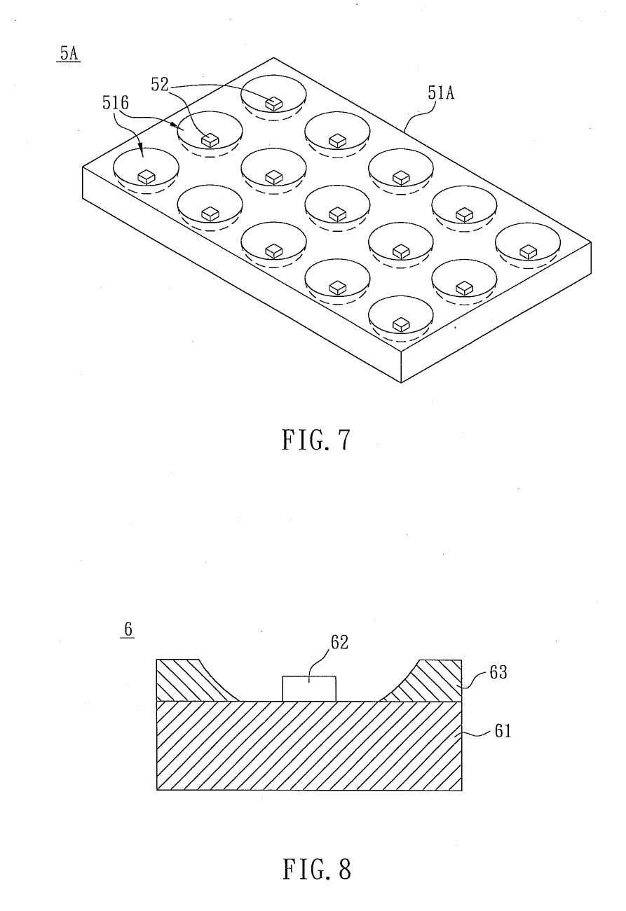

The inner edge of the cavity 516 can have a reflective surface. Consequently, when the heat-emitting device 52 emits light, the reflective surface can reflect the light and thus enhance the light emitting efficiency. The reflective surface can be formed on the inner edge of the cavity 516 by way of plating, electroless plating, coating or transfer printing. In addition, as shown in FIG. 7, a co-fired ceramic module 5A includes a ceramic substrate 51A, a plurality of cavities 516, and a plurality of heat-emitting device 52. The heat-emitting device 52 is disposed in the cavity 516 and the cavities 516 can be arranged in an array.

### Sixth Embodiment

Referring to FIG. 8, a co-fired ceramic module 6 according to a sixth embodiment of the invention includes a ceramic substrate 61, at least one heat-emitting device 62 and a frame 63, which has at least one cavity and is disposed on the ceramic substrate 61. The heat-emitting device 62 is disposed in the cavity formed by the frame 63. The material of the frame 63 can be a ceramic material, metal or a polymeric material. The shape of the inner edge of the cavity can have many aspects, such as a curved, inclined, upright or ladder-like surface, similar to co-fired ceramic module shown in FIGS. 5, 6A, 6B and 6C. In addition, the inner edge of the cavity can have a reflective surface for reflecting light. The reflective surface can be formed on the inner edge of the cavity by way of plating, electroless plating, coating or transfer printing. In addition, when there are many cavities, the cavities can be arranged in an array.

### Seventh Embodiment

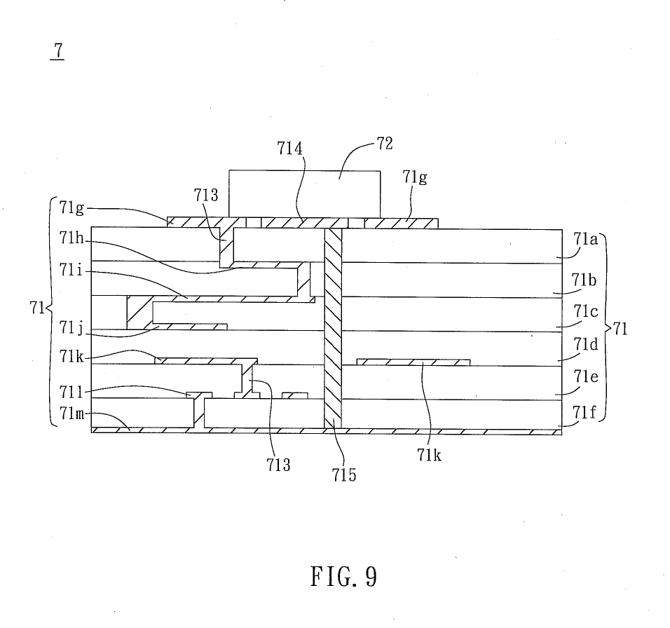

In addition to the high thermal conductivity material, the co-fired ceramic module of the invention further includes a high electroconductive material, which has a high coefficient of heat conductivity and is, for example but not limited to, silver or silver-palladium (Ag—Pd). Referring to FIG. 9, a co-fired ceramic module 7 according to a seventh embodiment of the invention includes a ceramic substrate 71 and at least one heat-emitting device 72.

The ceramic substrate 71 includes a plurality of thermoconductive layers 71a to 71f and a plurality of electroconductive layers 71g to 71m. Each of the thermoconductive layers 71a to 71f has the high thermal conductivity material, each of the electroconductive layers 71g to 71m has the high electroconductive material, and the electroconductive layers 71g to 71m and the thermoconductive layers 71a to 71f are stacked alternately. The heat-emitting device 72 is disposed on one of the thermoconductive layers. Herein, the heat-emitting device 72 is disposed on the thermoconductive layer 71a. The heat-emitting device 72 is electrically connected to at least one of the electroconductive layers. Herein, the heat-emitting device 72 is electrically connected to the electroconductive layer 71g. In addition, the ceramic substrate 71 further has a metal layer 714, at least one thermal via hole 715 and at least one via hole 713. The metal layer 714 and the thermal via hole 715 are for conducting the heat, and the via hole 713 is for transmitting the electric signal.

The method of manufacturing the ceramic substrate 71 will be described in the following. First, the ceramic material, the inorganic adhesive, the high thermal conductivity material and other necessary materials are mixed to form the slurry. Next, the slurry is shaped into a plurality of pre-mold plates using the scraper. A circuit pattern made of the high electroconductive material is formed on each of the pre-mold plates by way of screen printing. Then, the pre-mold plates are stacked and sintered at the temperature lower than 1000° C. so that the ceramic substrate 71 is obtained. The pre-mold plate is formed with the thermoconductive layers 71a to 71f, and the circuit pattern is formed with the electroconductive layers 71g to 71m.

In summary, the high thermal conductivity material is added to the co-fired ceramic module of the invention and then co-fired with the co-fired ceramic module to form the ceramic substrate. Thus, the high thermoconductive efficiency can be provided to the heat-emitting device. Compared with the prior art, the invention can have the high thermoconductive efficiency without modifying the structure of the sintered ceramic substrate so that the production time can be saved, the original structural intensity is free from being damaged, and the reliability is enhanced.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A co-fired ceramic module comprising:
a ceramic substrate having at least one high thermal conductivity material; and
at least one heat-emitting device disposed on the ceramic substrate.

2. The co-fired ceramic module according to claim 1, wherein the ceramic substrate is a low-temperature co-fired ceramics (LTCC) substrate.

3. The co-fired ceramic module according to claim 1, wherein the ceramic substrate is formed by sintering a pre-mold plate, formed by mixing a ceramic material, an inorganic adhesive and the high thermal conductivity material, at a temperature lower than 1000° C.

4. The co-fired ceramic module according to claim 1, wherein the ceramic substrate is a carrier or a circuit board.

5. The co-fired ceramic module according to claim 1, wherein the high thermal conductivity material comprises aluminum nitride, silicon carbide, sapphire or beryllium oxide (BeO).

6. The co-fired ceramic module according to claim 1, wherein the heat-emitting device is a light-emitting diode (LED), a solar cell, a chip, a package body, a passive device or an active device.

7. The co-fired ceramic module according to claim 1, wherein the heat-emitting device is disposed on the ceramic substrate through an intermetallic material, solder tin or silver paste, or connected to the substrate by flip-chip bonding, quad flat package (QFP), surface mount technology (SMT), or pin grid array (PGA) package.

8. The co-fired ceramic module according to claim 1, wherein the ceramic substrate has a metal layer connected to the heat-emitting device.

9. The co-fired ceramic module according to claim 1, wherein the ceramic substrate has at least one via hole.

10. The co-fired ceramic module according to claim 1, wherein the ceramic substrate has a plurality of connection pads, and the heat-emitting device is directly connected to the connection pads or connected to the connection pads by wire bonding or ball grid array packaging.

11. The co-fired ceramic module according to claim 1, wherein the heat-emitting device is wire-bonded to a circuit board.

12. The co-fired ceramic module according to claim 1, wherein the ceramic substrate has an electroconductive path and a thermoconductive path parallel to or perpendicular to the electroconductive path.

13. The co-fired ceramic module according to claim 1, wherein the ceramic substrate has an electroconductive path and a thermoconductive path extending in the same or different directions.

14. The co-fired ceramic module according to claim 1, wherein the ceramic substrate has at least one cavity and the heat-emitting device is disposed in the cavity.

15. The co-fired ceramic module according to claim 14, wherein an inner edge of the cavity has an inclined surface, an upright surface, a curved surface or a ladder-like surface.

16. The co-fired ceramic module according to claim 14, wherein the cavity is shaped by planning, scraping, grinding or imprinting, then sintering and polishing.

17. The co-fired ceramic module according to claim 14, wherein the cavity is formed by sintering a pre-molding plate and then planning, scraping or grinding the pre-mold plate.

18. The co-fired ceramic module according to claim 14, wherein the cavity is formed by punching a pre-mold plate, then planning, scraping, grinding or imprinting the pre-mold plate, and sintering and polishing the pre-mold plate.

19. The co-fired ceramic module according to claim 14, wherein the cavity is formed by punching a pre-mold plate, then sintering the pre-mold plate, and then planning, scraping or grinding the pre-mold plate.

20. The co-fired ceramic module according to claim 14, wherein the inner edge of the cavity has a reflective surface formed by plating, electroless plating, coating or transfer printing.

21. The co-fired ceramic module according to claim 1, further comprising a frame disposed on the ceramic substrate and having at least one cavity, and the heat-emitting device is disposed in the cavity.

22. The co-fired ceramic module according to claim 21, wherein the frame comprises a ceramic material, metal or a polymeric material.

23. The co-fired ceramic module according to claim 1, wherein the ceramic substrate further has at least one high electroconductive material, silver or silver-palladium.

24. The co-fired ceramic module according to claim 1, wherein the ceramic substrate comprises:
a plurality of thermoconductive layers with a high thermal conductivity material, wherein the heat-emitting device is disposed on one of the thermoconductive layers; and
a plurality of electroconductive layers with the high electroconductive material, wherein the electroconductive layers and the thermoconductive layers are arranged alternately, and the heat-emitting device is electrically connected to at least one of the electroconductive layers.

25. The co-fired ceramic module according to claim 24, wherein the ceramic substrate further comprises a metal layer and at least one via hole.

26. The co-fired ceramic module according to claim 24, wherein the ceramic substrate is formed by:
preparing slurry comprising a ceramic material, an inorganic adhesive and the high thermal conductivity material;
forming the slurry into a plurality of pre-mold plates;
respectively forming circuit patterns on the pre-mold plates by screen printing, wherein a material of each of the circuit patterns comprises the high electroconductive material; and
stacking the pre-mold plates and sintering the pre-mold plates at a temperature lower than 1000° C.
